(19) United States
(12) Patent Application Publication
(10) Pub. No.: US 2010/0289599 A1
(43) Pub. Date: Nov. 18, 2010

(54) High Performance RF Rx Module

(76) Inventors: Thomas Knecht, Dundee, IL (US); Glen Reeser, Palatine, IL (US); Reddy Vangala, Albuquerque, NM (US)

Correspondence Address: CTS Corporation, 2375 Cabot Drive, Lisle, IL, 60532, US

(21) Appl. No.: 12/778,304

(22) Filed: May 12, 2010

Related U.S. Application Data
(60) Provisional application No. 61/216,367, filed on May 15, 2009.

(51) Int. Cl. H03H 7/48

(52) U.S. Cl. 333/132

(57) ABSTRACT

An RF module for use in an RF signal transceiver system. In one embodiment, the RF module comprises a substrate having at least a duplexer filter, first and second bandpass filters and first and second low noise amplifiers mounted thereon. The substrate includes respective edges having respective RF signal input/output and supply voltage terminals defined therein. The overall dimensions of the substrate and/or the location of the respective terminals have been predetermined in a manner which allows the same size substrate with the same terminal locations to be used for several different air interfaces such as, for example, EGSM, GSM 850, DCS, and PCS applications, irrespective of a specific air interface need for differently sized and/or additional filters.

### CROSS-REFERENCE TO RELATED APPLICATIONS

This application claims the benefit of the filing date and disclosure of U.S. Provisional Application Ser. No. 61/216,367 filed on May 15, 2009 which is explicitly incorporated herein by reference as are all references cited therein.

### FIELD OF THE INVENTION

The invention relates to a module and, more particularly, to a high performance radio frequency (RF) frequency division duplex receive (Rx) module adapted for use in satellite backhaul applications or the front end of a cellular base station such as, for example, a picocell communication base station.

### BACKGROUND OF THE INVENTION

There are currently several types of cellular/wireless communication base stations or RF signal transceiver systems for the transmission and reception of signals over several different available RF signal air interfaces including, for example, EGSM, GSM 850, DCS, PCS, and LTE. These transceiver systems include picocells, i.e., base stations which are approximately 8″×18″ in size, that are adapted for deployment inside buildings such as shopping malls, office buildings or the like, and generate about 0.25 to 1 watts of power. The coverage of a picocell is about 50 yards.

Picocells in use today typically include a “motherboard” upon which various electrical components are mounted by the customer. A front end portion of the motherboard (i.e., the RF transceiver section thereof located roughly between the picocell antenna and mixers thereof) is currently referred to in the art as the “node B local area front end,” i.e., a portion of the picocell on which all the radio frequency control electrical components have been mounted including the required filters, amplifiers, couplers, and the like.

While the configuration and structure of currently available motherboards has proven satisfactory, a disadvantage is the fact that each air interface such as, for example, EGSM, GSM 850, DCS, or PCS currently requires the transceiver system to include its own separate motherboard with all of the required components specific to the particular air interface being utilized.

There thus remains a need for a module designed to allow a transceiver system to use the same motherboard irrespective of the air interface being utilized.

### SUMMARY OF THE INVENTION

The present invention relates generally to a radio frequency (RF) module such as, for example, a frequency division duplex receive (Rx) module which is operable over a plurality of air interfaces and, in one embodiment, comprises a substrate having at least a duplexer filter, a first low noise amplifier and a first bandpass filter located and interconnected thereon. According to the invention, the substrate includes a predetermined size and further includes respective edges having respective RF signal input/output terminals and at least a first supply voltage terminal defined at predetermined terminal locations which allow the same substrate with the same size and the same terminal locations to be used for a plurality of the air interfaces.

In one embodiment, a second low noise amplifier and a second bandpass filter are located and interconnected on the substrate to the first bandpass filter and the substrate includes opposed first and second longitudinal substrate edges and opposed first and second transverse substrate edges wherein an RF receive signal output terminal is defined along the first transverse edge, an RF antenna signal input/output terminal is defined along the second transverse edge, an RF signal transmit input terminal is defined along the second longitudinal edge and first and second supply voltage terminals are defined along the first and second longitudinal edges respectively.

In one embodiment, the duplexer filter is mounted on the substrate adjacent the second transverse substrate edge, the second bandpass filter is located on the substrate adjacent the first transverse substrate edge, the first bandpass filter is located on the substrate between the duplexer filter and the second bandpass filter, the first low noise amplifier is located on the substrate and interconnected between the duplexer filter and the first bandpass filter, and the second noise amplifier is located on the substrate and interconnected between the first bandpass filter and the second bandpass filter.

In a further embodiment, a third low noise amplifier is located on the substrate and interconnected between the first low noise amplifier and the first bandpass filter.

Other advantages and features of the present invention will be more readily apparent from the following detailed description of two embodiments of the invention, the accompanying drawings, and the appended claims.

### BRIEF DESCRIPTION OF THE DRAWINGS

These and other features of the invention can best be understood by the following description of the accompanying FIGURES as follows:

FIG. 1 is a perspective view of a high performance RF Rx module in accordance with the present invention with the cover thereon;

FIG. 2 is one block embodiment of an RF Rx module in accordance with the present invention;

FIG. 3 is a simplified top plan view of the substrate of an RF Rx module embodying the block embodiment of FIG. 2;

FIG. 4 is an alternate block embodiment of an RF Rx module in accordance with the present invention; and

FIG. 5 is a simplified top plan view of the substrate of an RF Rx module embodying the block embodiment of FIG. 4.

### DETAILED DESCRIPTION OF THE EMBODIMENTS

While this invention is susceptible to embodiments in many different forms, this specification and the accompanying FIGURES disclose two representative RF Rx module embodiments as examples of the present invention which are adapted for use in, for example, the front end of a picocell cell phone base station, or in satellite backhaul applications. The invention is not intended, however, to be limited to the embodiments or applications so described.

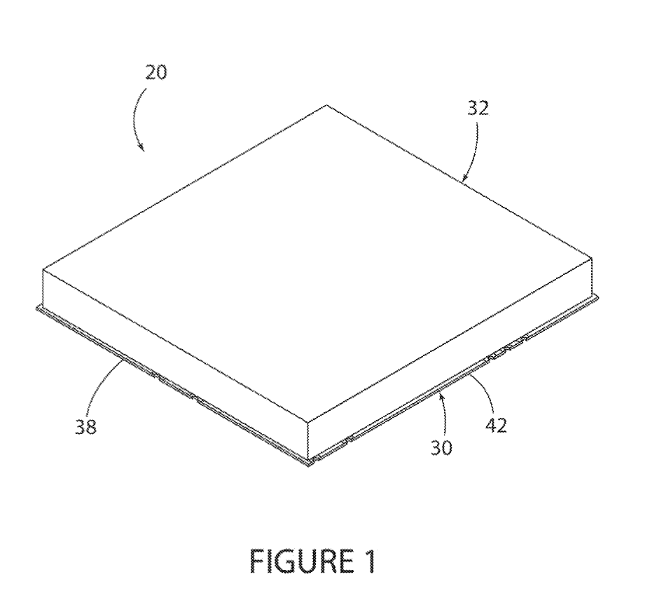

FIG. 1 depicts an RF (radio frequency) (FDD) frequency division duplex Rx (receive) module, generally designated 20, constructed in accordance with the present invention which generally comprises two main components: a substrate 30 and a cover or lid 32.

In the embodiment shown, substrate 30 is a printed circuit board made of a plurality of layers of GETEK®, FR408, or the like laminate material and is about 1 mm (i.e., 0.040 inches) in thickness. Lid 32, which is adapted to cover the full area of the substrate 30, is preferably brass with a Cu/Ni/Sn (copper/nickel/tin) plated material for RoHS compliance purposes. The lid 32 acts both as a dust cover and a Faraday shield.

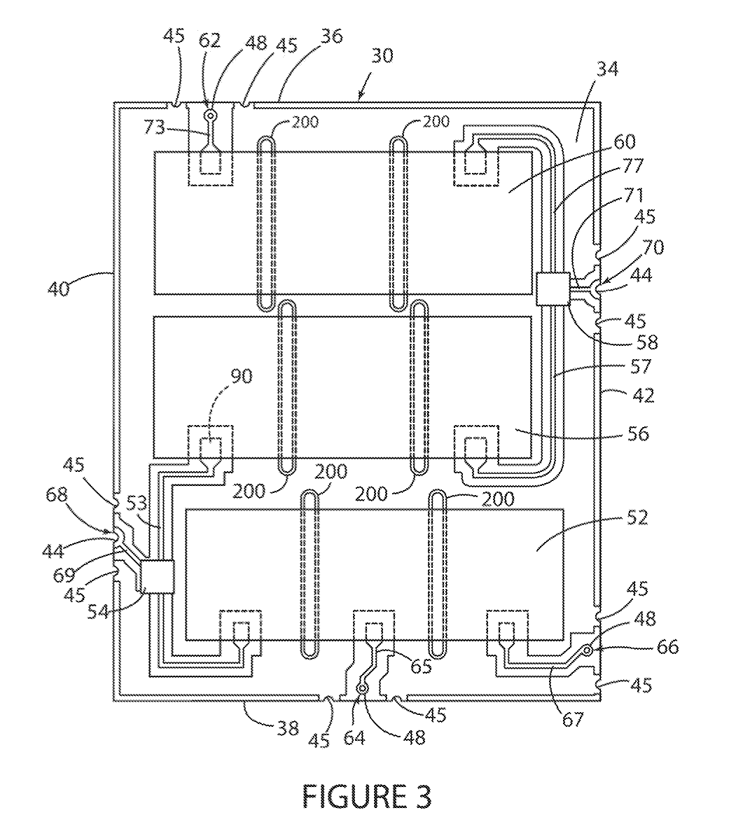

As shown in FIG. 3, generally rectangularly-shaped substrate 30 has a top or upper surface 34, a bottom or lower surface (not shown) and an outer peripheral circumferential edge defining opposed first and second upper and lower transverse faces or edges 36 and 38 and opposed third and fourth longitudinal faces or edges 40 and 42.

Castellations 44 and 45 and through-holes 48 are defined and located about the outer peripheral edge of the substrate 30. Castellations 45 define the respective ground terminals of the module 20, the castellations 44 define the respective supply voltage input terminals of the module 20, and the through-holes 48 define the respective RF signal input/output terminals of the module 20 as described in more detail below.

Castellations 44 and 45, as known in the art, are defined by metallized semi-circular grooves which have been carved out of the respective substrate edges and extend between the respective top and bottom surfaces of the substrate 30. In the embodiment of FIG. 3, the upper transverse edge 36 defines two spaced-apart castellations 45 on opposite sides of a through-hole 48, the lower transverse edge 38 defines two spaced-apart castellations 45 on opposite sides of another through-hole 48, the longitudinal side edge 40 defines two spaced-apart castellations 45 on opposite sides of a castellation 44 and the longitudinal side edge 42 defines five castellations, i.e., two castellations 45 on opposite sides of another through-hole 48 and two other castellations 45 on opposite sides of another castellation 44. Castellations 44 and 45 and through-holes 48, and, more specifically, the conductive copper material covering the same creates an electrical path between the top and bottom surfaces of the substrate 30.

Although not shown in any of the FIGURES, it is understood that, as known in the art, castellations 45 are coupled to a ground layer of conductive material on the bottom surface (not shown) and further that respective castellations 44 and through-holes 48 are coupled to respective strips/pads of conductive material on the bottom surface (not shown) of the substrate 30 which are separated from the ground layer of conductive material on the bottom surface (not shown) and define respective RF signal input/output and supply voltage input terminals.

As known in the art, and although not shown in any of the FIGURES, the pads defined on the bottom surface (not shown) of the substrate 30 allow the module 20 to be directly surface mounted, by reflow soldering or the like, to corresponding pads located on the top surface of the motherboard (not shown) at the front end of a picocell (not shown) or the like.

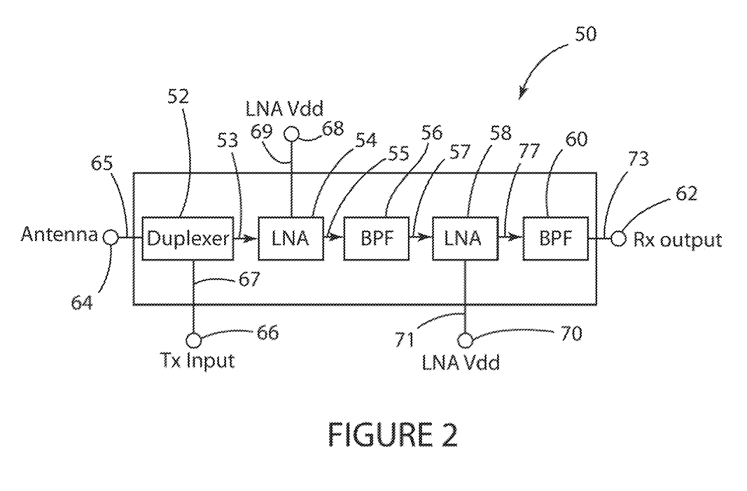

FIG. 2 depicts one block embodiment of an RF signal Rx circuit 50 adapted for use in RF Rx module 20 which includes a duplexer filter (Duplexer) 52 coupled to and in communication with a first low noise amplifier (LNA) 54 via a circuit line 53 which, in turn, is coupled to and in communication with a first bandpass filter (BPF) 56 via a circuit line 55 which, in turn, is coupled to and in communication with a second low noise amplifier (LNA) 58 via a circuit line 57 which, in turn, is coupled to and in communication with, a second bandpass filter (BPF) 60 via a circuit line 77 which, in turn, is coupled to and in communication with a receive (Rx) output terminal or pin 62 via a circuit line 73 which, in turn, is adapted to be coupled to a corresponding Rx signal port or pad (not shown) on the motherboard of a picocell or the like.

RF signal Rx circuit 50 is adapted to receive and transmit an antenna signal via RF antenna signal input/output terminal or pin 64 which is coupled to and in communication with the input of duplexer filter 46 via a circuit line 65.

With continued reference to FIG. 2, Rx circuit 50 further includes an RF signal transmit (Tx) signal input terminal or pin 66 coupled to the RF Tx signal port (not shown) of a picocell at one end and to duplexer filter 52 at the other end via a circuit line 67.

Vdd (power amplifier supply voltage) is supplied to respective low noise amplifiers 54 and 58 through respective LNA Vdd supply voltage input terminals or pins 68 and 70 via respective circuit lines 69 and 71.

One simplified embodiment of the layout of the substrate 30 of the module 20 incorporating the block elements shown in FIG. 2 is shown in FIG. 3 where antenna pad or terminal 64 is defined by the through-hole 48 located along and spaced from the bottom transverse edge 38 of the substrate 30; RF Rx output signal terminal or pin 62 is defined by the through-hole 48 located along the upper transverse edge 36 of the substrate 30; low noise amplifier supply voltage (Vdd) terminal or pin 68 is defined by the castellation 44 located along the longitudinal side edge 40 of substrate 30; and both the low noise amplifier supply voltage (Vdd) terminal or pin 70 for low noise amplifier 58 and the RF Tx signal input terminal or pin 66 are defined by the castellation 44 and the through-hole 48 respectively located along the longitudinal side edge 42 of the substrate 30.

The incorporation of the RF Tx signal input terminal or pin 66 on the substrate 30 allows a power amplifier (not shown) to be mounted directly to either the motherboard (not shown) or a heat-sink (not shown) for optimum thermal dissipation.

In the embodiment shown, terminal 68 on the longitudinal side substrate edge 40 is positioned adjacent but spaced from the lower transverse substrate edge 38; terminal 64 is located generally centrally along the lower transverse substrate edge 38; terminal 66 on the longitudinal side substrate edge 42 is positioned adjacent but spaced from the lower transverse substrate edge 38; terminal 70 which is also located on the longitudinal side substrate edge 42 is spaced from the terminal 66 and is positioned adjacent the upper transverse substrate edge 36; and the terminal 62 located on the upper transverse substrate edge 36 is positioned adjacent but spaced from the longitudinal side substrate edge 40.

In the embodiment shown, duplexer filter 52 is located on the substrate 30 in a relationship wherein the long side of duplexer filter 52 is positioned adjacent, spaced from, and parallel to the lower transverse edge 38 of substrate 30; bandpass filter 60 is located on the substrate 30 in a relationship wherein the long side of bandpass filter 60 is positioned adjacent, spaced from, and parallel to the upper transverse edge 36 of substrate 30; and the bandpass filter 56 is generally centered and located on the substrate 30 between the duplexer filter 52 and the bandpass filter 60 and, more specifically, in a relationship wherein the opposed long side edges of the bandpass filter 56 are positioned in a relationship spaced from and parallel to the long sides of duplexer filter 46, the bandpass filter 50, and the left and right side transverse edges 40 and 42 of the substrate 30.

The plurality of circuit lines 53, 55, 57, 67, 69, 71, and 73 and pads 90, which are formed on the substrate top surface 34 are made of copper or the like conductive material and extend between and interconnect respective ones of the terminals and electrical components as described in more detail below. The metallization system is preferably ENIG, electroless nickel/immersion gold over copper.

Circuit line 65 extends between and interconnects the RF antenna terminal 64 and the duplexer filter 52. Circuit line 67 extends between and interconnects the RF Tx signal terminal 66 and the duplexer filter 52. Circuit line 73 extends between and interconnects the output of bandpass filter 60 and the RF Rx signal output terminal 62. Circuit line 53 extends between and interconnects the duplexer filter 52 and the first bandpass filter 56. Circuit line 57 extends between and interconnects the first bandpass filter 56 and the second bandpass filter 60.

Low noise amplifier 54 is located on the substrate 30 between the longitudinal side substrate edge 40 and the left side edge of duplexer filter 52. Low noise amplifier 58 is located on the substrate 30 between the longitudinal side substrate edge 42 and the right side edge of band pass filter 56. Low noise amplifier 54 is located on circuit line 53 and low noise amplifier 58 is located on circuit line 57. Circuit line 69 couples and interconnects the LNA Vdd terminal 68 to the low noise amplifier 54 and circuit line 71 couples and interconnects the LNA Vdd supply voltage terminal 70 to the low noise amplifier 58.

Although not shown or described in detail herein, it is understood that the low noise amplifiers 54 and 58 are placed and interconnected between the respective filters 52, 56, and 60 to amplify the signal and assure a minimum NF (noise figure) and that a plurality of appropriate resistors, capacitors, and inductors are located and fixed along one or more of the respective circuit lines for performing decoupling, filtering, and biasing functions as known in the art.

As shown in FIG. 3, the substrate 30 also includes a plurality of elongated slots 200 formed therein and extending between the top and bottom surfaces thereof. In the embodiment shown, a pair of spaced-apart and parallel slots 200 are formed in the region of the substrate 200 located below each of the filters 52, 56, and 60 and are oriented in a relationship generally normal to the length of each of the filters 52, 56, and 60. Moreover, in the embodiment shown, the slots 200 are formed and positioned in the substrate 30 in a relationship wherein the respective opposed end portions of each of the slots 200 protrude outwardly from the opposed top and bottom longitudinal edges of the respective filters 52, 56, and 60.

The slots 200 reduce the thermal mismatch between the material of the filters 52, 56, and 60 and the material of the substrate 30 during heating and cooling of the module 20. For example, after the module 20 cools down from the solder reflow operation in which the filters 52, 56, and 60 are soldered to the substrate 30, the substrate 30 and the filters 52, 56, and 60 are “frozen” together at about 200° C. Because the material of the substrate 30 has a thermal expansion coefficient which is four-five times greater than the thermal expansion coefficient of the ceramic material of the filters 52, 56, and 60, there are higher stresses in the ceramic material of the filters when the module 20 is cooled down to or below room temperature. The stresses in the ceramic material also increase as a function of the length and area of the bond between the ceramic material and the substrate material. The slots 200 reduce the effective board length or area between the ceramic and substrate materials by a factor of three, thus greatly reducing the induced stresses in the material of the ceramic filters 52, 56, and 60.

The overall dimension and area of the module 20 shown in FIGS. 1 and 3, which is determined by and dependent upon the size (i.e., the length and width) of the filters 52, 56, and 60 mounted on the substrate 30, is approximately 43 mm wide by 53 mm long by 11.2 mm maximum high. Thus, in the embodiment shown, the overall width of the module 20 is based upon the length of the largest filter while the overall length of the module 20 is based upon the combined width of the duplexer 52, the bandpass filter 56, and the bandpass filter 60.

In a like manner, the location of the respective RF signal input/output terminals 62, 64, and 66 and supply voltage terminals 68 and 70 along the respective first, second, third, and fourth substrate edges 36, 38, 40, and 42 is based upon the location and size (i.e., length and width) of the respective filters 52, 56, and 60 and the low noise amplifiers 54 and 58 mounted on the top surface 34 of the substrate 30.

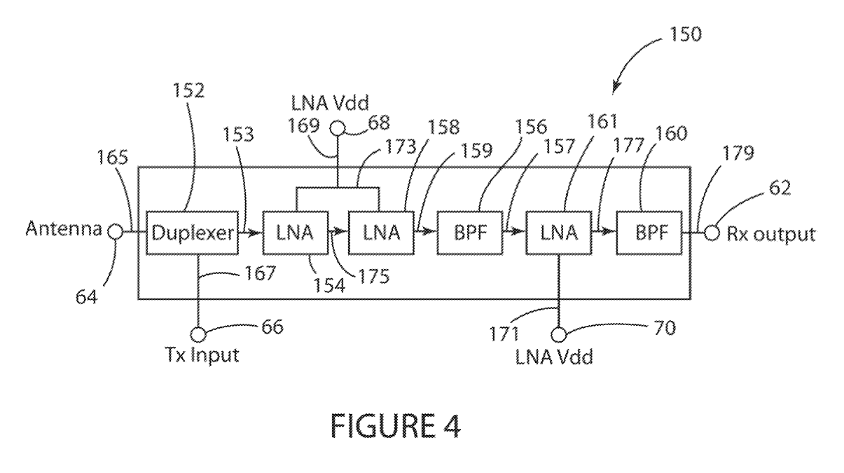

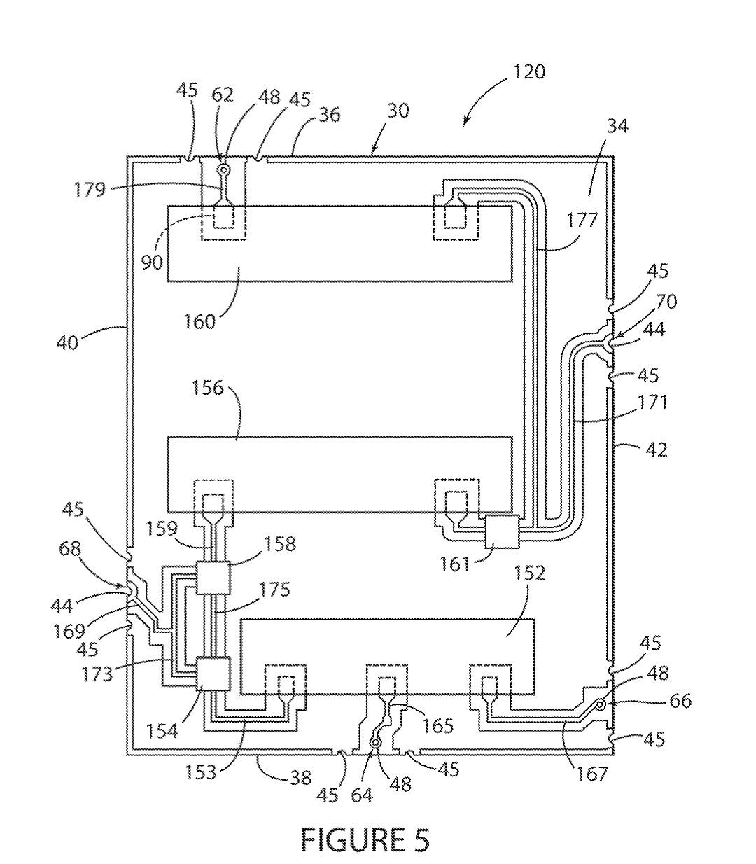

The two lower frequency applications or protocols, i.e., the EGSM and GSM 850 applications, use variations of the module embodiment 20 represented in FIGS. 1-3. The two higher frequency applications or protocols, i.e., the DCS and PCS applications at greater than about 1710 MHz, utilize variations of module embodiment 120, the block embodiment 150 of which is shown in FIG. 4 and a simplified representation of the substrate 30 of which is shown in FIG. 5 and described in more detail below.

As shown in FIGS. 4 and 5, RF Rx module 120 which, in the embodiment shown, is also a frequency division duplex (FDD) module, incorporates the following main components mounted on a substrate 30: a duplexer filter 152; first, second, and third low-noise amplifiers 154, 158, and 161, respectively; and first and second bandpass filters 156 and 160 respectively.

A circuit line 165 connects the RF antenna signal input/output terminal 64 to the input of duplexer filter 152 which, in turn, is connected to a first low noise amplifier (LNA) 154 via a circuit line 153 which, in turn, is connected to a second low noise amplifier (LNA) 158 via a circuit line 175 which, in turn, is connected to a first bandpass filter (BPF) 156 via a circuit line 159 which, in turn, is connected to a third low noise amplifier (LNA) 161 via a circuit line 157 which, in turn, is connected to a second bandpass filter (BPF) 160 via a circuit line 177 which, in turn, is connected to the RF receive (Rx) output signal terminal 62 via a circuit line 179.

A circuit line 169 connects a LNA Vdd terminal 68 to a circuit line 173 common to both of the low noise amplifiers 154 and 158 and a circuit line 171 connects LNA Vdd supply voltage input terminal 70 to the third low noise amplifier 161. Finally, a circuit line 167 connects an RF transmit (Tx) input signal terminal 66 to the duplexer filter (duplexer) 152.

In accordance with the present invention, each of the modules to be used in connection with each of the air interfaces such as, for example, EGSM, GSM 850, DCS, and PCS, including the modules 20 and 120 disclosed herein, are designed to share the same basic substrate 30 with the same footprint, i.e., with the same overall area or length and width dimensions and/or the same terminal locations to simplify, accelerate, and lower the cost of the module manufacturing and assembly process.

Thus, in accordance with the present invention, and to allow use of the same size substrate with the same terminal locations for at least each of the four air interfaces identified above, the substrate used in the air interface requiring the longest filter and the widest and greatest number of total filters is used as the template for each of the four modules including the modules 20 and 120. Inasmuch as the module 20 uses the longest filter and the widest and greatest number of total filters (i.e., duplexer filter 52 and additional bandpass filters 56 and 60), the substrate 30 of module 20 is the template used for the substrate to be used for each of the four modules, only two of which (the modules 20 and 120) have been shown and described herein.

In view of the above, and inasmuch as the substrate 30 of module 120 has the same overall area and dimensions and terminal placement/location as the substrate 30 of module 20, the same numerals have been used in FIGS. 4 and 5 to designate identical elements and the earlier description of such elements with regard to RF Rx module embodiment 20 and, more specifically the location and placement of terminals 62, 64, 66, 68 and 78 along the respective first, second, third, and fourth peripheral edges 36, 38, 40, and 42 of the substrate 30 of module 20, is incorporated herein by reference with respect to the RF Rx module embodiment 120 and, more specifically, the location and placement of the corresponding terminals 62, 64, 66, 68, and 70 along the respective first, second, third, and fourth edges 36, 38, 40, and 42 of the substrate 30 of the module 120 except as otherwise described below in more detail.

The only differences between the substrates 30 of respective RF Rx modules 20 and 120 is the selection, number, size, location and placement of the respective electrical components and circuit lines on the respective substrates 30, i.e., two variables which are dependent primarily on the size of the respective duplexer and bandpass filters which, in turn, then determines the position thereon on the substrates 30 of the various circuit lines which interconnect the same.

Each of the duplexer and bandpass filters 152, 156, and 160 of RF Rx module 120 shown in FIG. 5 is, as a result of the different applications, smaller in size than the respective duplexer and bandpass filters 52, 56, and 60 used on RF Rx module 20. Each of the duplexer and bandpass filters 152, 156 and 160 is, however, positioned and mounted on the substrate 30 in the same general locations as the duplexer 52 and bandpass filters 56 and 60 of the RF Rx module 20, and thus the description of the location and mounting of the duplexer 52 and bandpass filters 56 and 60 of RF Rx module 20 on the substrate 30 is incorporated herein by reference with respect to the location and mounting of the duplexer filter 152 and bandpass filters 156 and 160 on the substrate 30 of the RF Rx module 120.

Low noise amplifier 154 is located and mounted on the substrate 30 between the longitudinal side substrate edge 40 and the left side edge of the duplexer filter 152. Low noise amplifier 158 is located and mounted on the substrate 30 generally between the duplexer 152 and the bandpass filter 156 in a relationship generally co-linear with the low noise amplifier 154. Low noise amplifier 161 is located and mounted on the substrate 30 adjacent and spaced from the longitudinal side substrate edge 42 and between the right side ends of the duplexer filter 152 and the bandpass filter 156.

The plurality of circuit lines 153, 159, 165, 167, 169, 171, 173, 175, 177, and 179 identified in block form in FIG. 4 and shown in FIG. 5 are formed on the top surface 34 of the substrate 30 of RF Rx module 120, are made of copper or the like conductive material, and electrically interconnect the various components 152, 154, 156, 158, and 160 to each other and the respective terminals 62, 64, 66, 68, and 70 as described above in connection with FIG. 4, the description of which is incorporated herein by reference.

Further, and although not shown in FIG. 5, it is understood that RF Rx module 120, in a manner similar to RF Rx module 20, likewise incorporates appropriate resistors, capacitors, and inductors on the substrate 30 for performing decoupling, filtering, biasing, and other electrical functions as known in the art. Still further, and although not show or described herein, it is understood that module 120 likewise incorporates a lid similar to the lid 32 of module 20.

What has thus been described are RF Rx modules 20 and 120 which, while incorporating differently sized and/or additional filter and electrical components to satisfy different application requirements, are adapted to advantageously share the same size substrate 30 with the same RF signal input/output and supply voltage terminals 62, 64, 66, 68, and 70 to simplify and expedite the manufacturing and assembly process and thus provide lower cost RF Rx modules.

While the invention has been taught with specific reference to the two module embodiments 20 and 120, it is understood that someone skilled in the art will recognize that changes can be made in form and detail such as, for example, to the selection, number, placement, interconnection values, and patterns of the various RF elements and circuits, without departing from the spirit and the scope of the invention as defined in the appended claims. The described embodiments are to be considered in all respects only as illustrative and not restrictive.

We claim:

1. An RF module for use in a wireless communication system operable over a plurality of air interfaces, the module comprising a substrate having at least a duplexer filter, a first low noise amplifier and a first bandpass filter located and interconnected thereon, the substrate including a predetermined size and further including respective edges having respective RF signal input/output terminals and at least a first supply voltage terminal defined at predetermined terminal locations which allow the same substrate with the same size and the same terminal locations to be used for a plurality of the air interfaces.

2. The RF module of claim 1 further comprising a second low noise amplifier and a second bandpass filter located and interconnected on the substrate to the first bandpass filter, the substrate including opposed first and second longitudinal substrate edges and opposed first and second transverse substrate edges wherein an RF receive signal output terminal is defined along the first transverse edge, an RF antenna signal input/output terminal is defined along the second transverse edge, an RF signal transmit input terminal is defined along the second longitudinal edge and first and second supply voltage terminals are defined along the first and second longitudinal edges respectively.

3. The RF module of claim 2 wherein the duplexer filter is mounted on the substrate adjacent the second transverse substrate edge, the second bandpass filter is located on the substrate adjacent the first transverse substrate edge, the first bandpass filter is located on the substrate between the duplexer filter and the second bandpass filter, the first low noise amplifier is located on the substrate and interconnected between the duplexer filter and the first bandpass filter, and the second noise amplifier is located on the substrate and interconnected between the first bandpass filter and the second bandpass filter.

4. The RF module of claim 3, further comprising a third low noise amplifier located on the substrate and interconnected between the first low noise amplifier and the first bandpass filter.

5. The RF module of claim 1 wherein the plurality of air interfaces include EGSM, GSM, DCS, and PCS.

6. An RF module comprising:
a substrate including opposed first and second substrate edges and opposed third and fourth substrate edges wherein an RF signal output terminal is defined along the first substrate edge, an RF signal antenna terminal is defined along the second substrate edge, a first supply voltage terminal is defined along the third substrate edge, and an RF signal input terminal and a second supply voltage terminal are defined along the fourth substrate edge;
a duplexer filter located on the substrate adjacent the second substrate edge;
a first bandpass filter located on the substrate adjacent the duplexer filter;
a second bandpass filter located on the substrate adjacent the first substrate edge, the first bandpass filter being located on the substrate between the duplexer filter and the second bandpass filter;
a first low noise amplifier located on the substrate and interconnected between the duplexer filter and the first bandpass filter;
a second low noise amplifier located on the substrate and interconnected between the first bandpass filter and the second bandpass filter; and
a plurality of circuit lines formed on the substrate and interconnecting the respective filters, amplifiers, and terminals.

7. The RF module of claim 6 further comprising a third low noise amplifier located on the substrate and interconnected between the first low noise amplifier and the first bandpass filter.

8. An RF module comprising a substrate including an RF signal output terminal defined along a first edge of the substrate, an RF signal antenna terminal defined along a second edge of the substrate, a first supply voltage terminal defined along a third edge of the substrate, and an RF signal input terminal defined along a fourth edge of the substrate.

9. The RF module of claim 8 further comprising at least a duplexer filter located on the substrate adjacent and parallel to the second edge of the substrate and a first bandpass filter also located on the substrate, the RF module further comprising a first low noise amplifier located on the substrate and interconnected between the duplexer filter and the first bandpass filter, the first supply voltage terminal being connected to the first low noise amplifier.

10. The RF module of claim 9 wherein at least a first slot is formed in a region of the substrate located below the duplexer filter and the first bandpass filter.

11. The RF module of claim 9 further comprising a second bandpass filter located on the substrate adjacent and parallel to the first edge of the substrate, the first bandpass filter being located on the substrate between the duplexer filter and the second bandpass filter, a second low noise amplifier located on the substrate and interconnected between the first and second bandpass filters, and a second supply voltage terminal defined along the fourth edge of the substrate and connected to the second low noise amplifier.

12. The RF module of claim 11 wherein at least a first slot is formed in a region of the substrate located below the second bandpass filter.

13. The RF module of claim 11 further comprising a third low noise amplifier located on the substrate and interconnected between the first low noise amplifier and the first bandpass filter, the first supply voltage terminal being connected to the third low noise amplifier.
